(19) United States
(12) Patent Application Publication
(10) Pub. No.: US 2012/0193496 A1
(43) Pub. Date: Aug. 2, 2012

(54) HOLDER FOR HANDHELD ELECTRONIC DEVICE

(76) Inventor: Chin-Chu LI, Wu Chi (TW)

(21) Appl. No.: 13/084,481

(22) Filed: Apr. 11, 2011

(30) Foreign Application Priority Data
Jan. 28, 2011 (TW) 100202153

(51) Int. Cl. H05K 7/00

(52) U.S. Cl. 248/316.1

(57) ABSTRACT

A holder for being placed by a handheld electronic device is disclosed. The holder includes a board having two long holes and two fastener assemblies separately corresponding to the long holes. Each of the fastener assemblies has a post penetrating the long hole, a bracket and a supporting pad. The bracket and supporting pad are disposed on two opposite sides of the board and at two ends of the post.

### BACKGROUND OF THE INVENTION

1. Technical Field

The invention relates to supporting devices, particularly to supporting devices for handheld electronic products. 2. Related Art

With rapid development of information technology, various handheld electronic devices, such as tablet PCs, GPSs and smart phones, appear in the market. These products provide users much assistance so that users may obtain information or deal with affairs without positional restrictions.

A handheld electronic device must be held in a hand of a user to operate. Users always feel uncomfortable if they have held a device for a long time. Thus some users prefer to put a handheld device on a support for operation. However, electronic devices usually generate a large amount of heat when working. An electronic device closely attached to a support will reduce its efficiency of heat dissipation because of poor air convection.

### SUMMARY OF THE INVENTION

A primary object of the invention is to provide a holder for a handheld electronic device, which can firmly hold a handheld electronic device.

Another object of the invention is to provide a holder for a handheld electronic device, which can applied to various devices with different sizes.

Still another object of the invention is to provide a holder for a handheld electronic device, which can increase efficiency of heat dissipation of the device by promoting air convection around the device.

To accomplish the above object, the holder of the invention includes a board having two long holes and two fastener assemblies separately corresponding to the long holes. Each of the fastener assemblies has a post penetrating the long hole, a bracket and a supporting pad. The bracket and supporting pad are disposed on two opposite sides of the board and at two ends of the post.

In an embodiment, the board is provided with heat dissipating holes.

In an embodiment, the two long holes are located at the same side of the board.

In an embodiment, the two long holes are located at two opposite angles of the board.

In an embodiment, a direction of each of the long holes is towards a center of the board.

In an embodiment, two sides of each of the long holes are separately provided with two slots, the long holes are separately parallel to adjacent two slots, and each of the fastener assemblies has two protrusions separately penetrating the slots.

In an embodiment, the board is provided with a fork gripper.

In an embodiment, the post is provided with an outer thread, and the supporting pad is correspondingly provided with a threaded hole for being screwed by the post.

In an embodiment, the supporting pad is formed with an anti-slip shape.

In an embodiment, each of the fastener assemblies has a flexible element put around the post and between the board and the bracket.

In comparison with prior art, the invention uses at least two fastener assemblies to clip a handheld electronic device on a board. And the board is upheaved by supporting pads so that the handheld electronic device is not closely attached on a table top. Thus the invention can increase efficiency of heat dissipation of the device by promoting air convection around the device

### BRIEF DESCRIPTION OF THE DRAWINGS

FIG. 1 is an assembled perspective view of the invention;

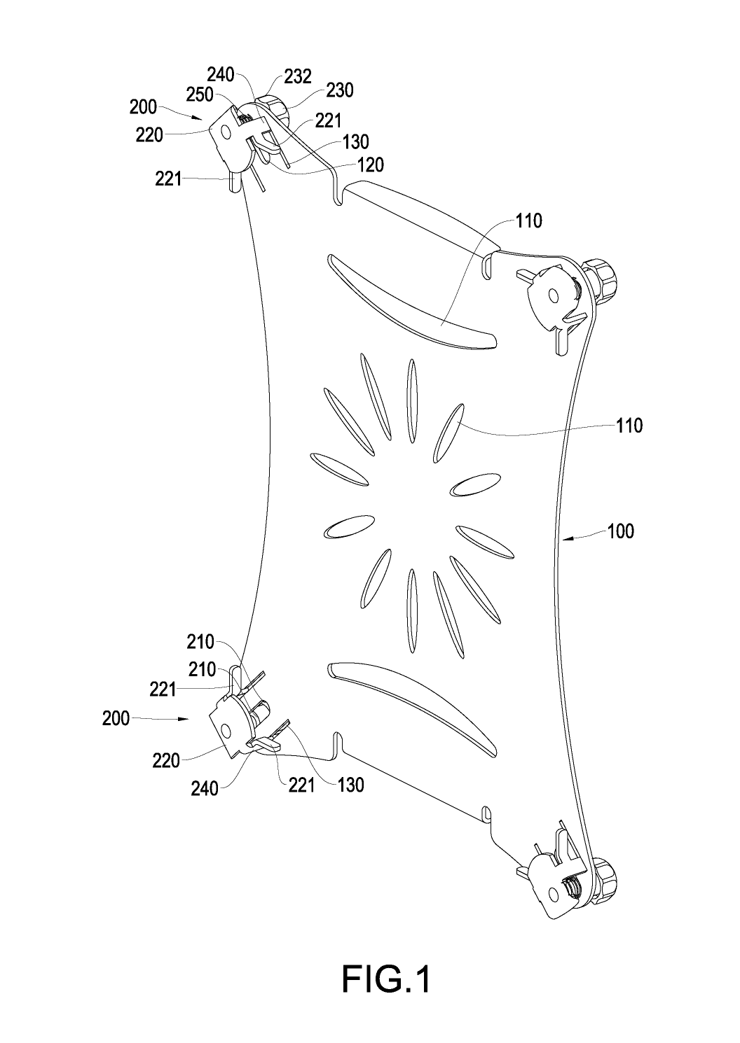

FIG. 2 is an exploded perspective view of the invention;

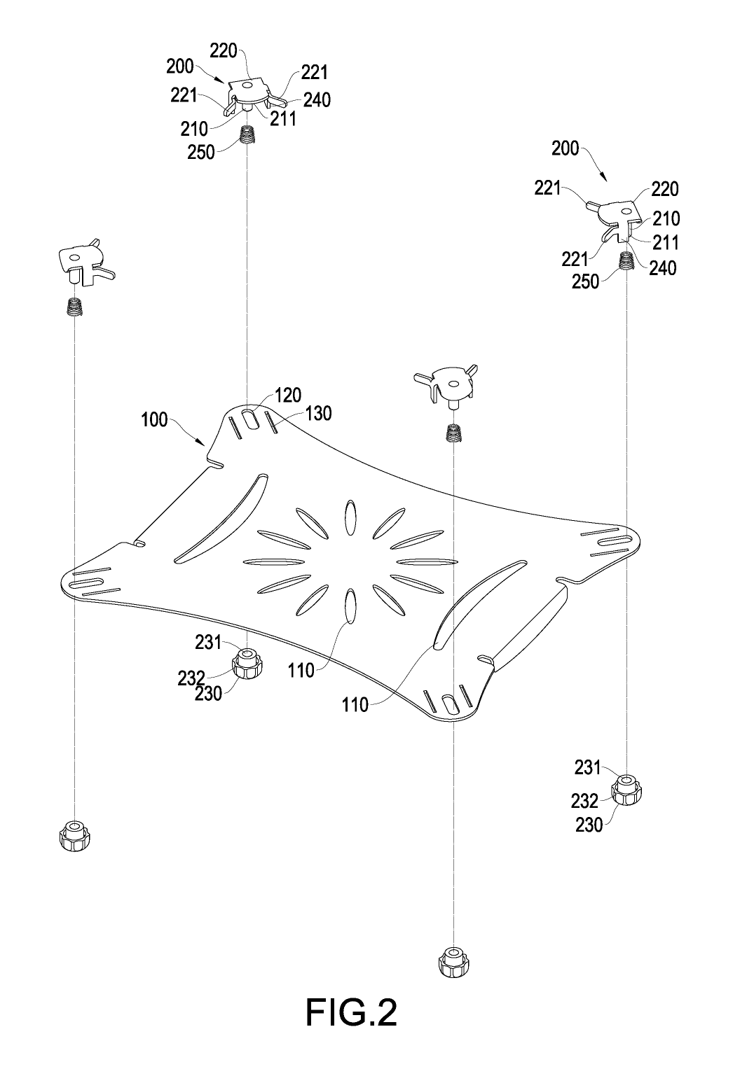

FIG. 3 is a partially enlarged exploded view of the invention;

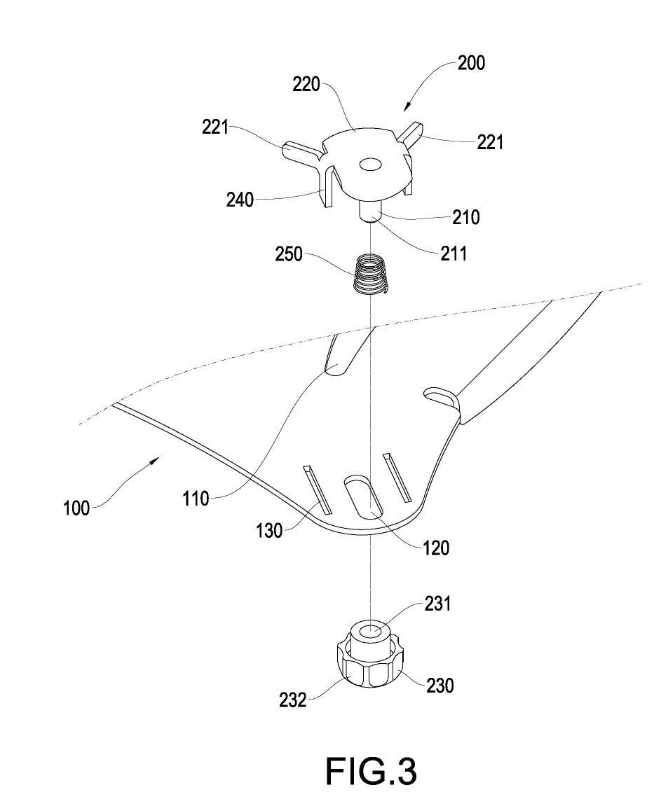

FIG. 4 is a schematic view showing typical application of the invention;

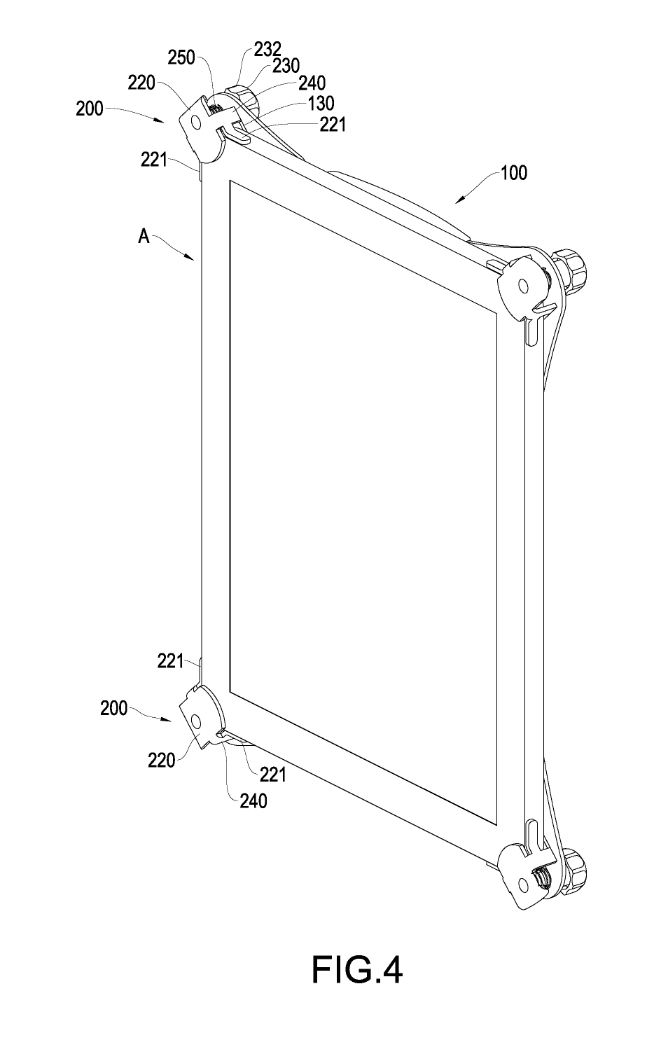

FIG. 5 is a top view of FIG. 4;

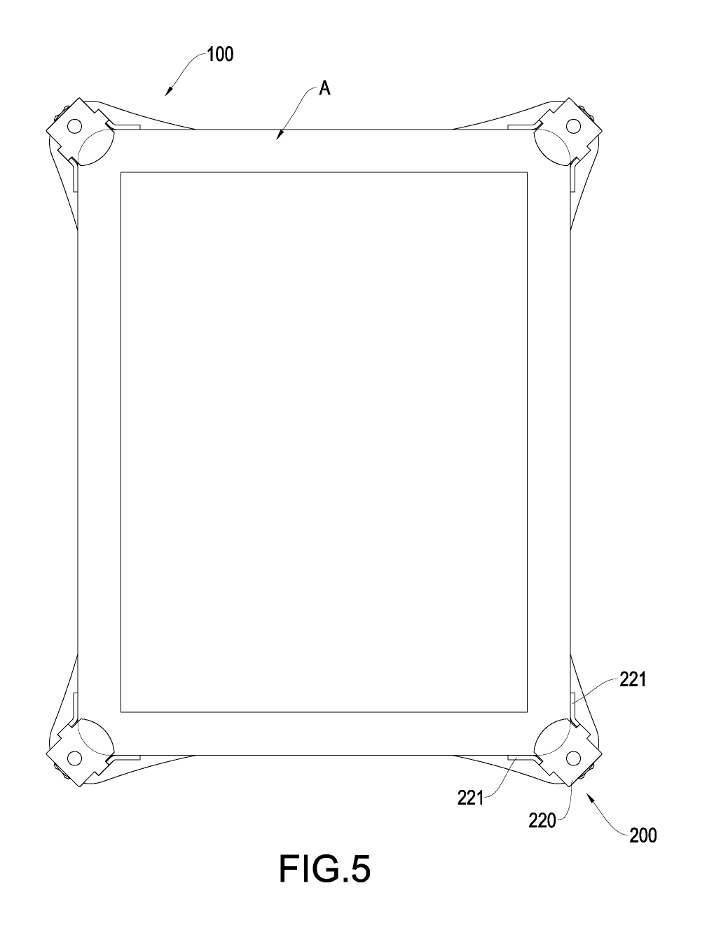

FIG. 6 is a cross-sectional view of FIG. 4; and

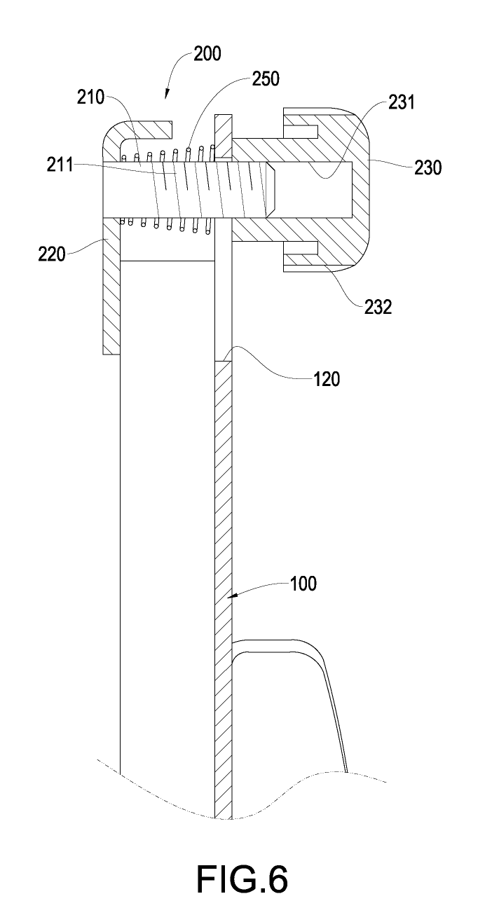

FIG. 7 is a top view of another application of the invention.

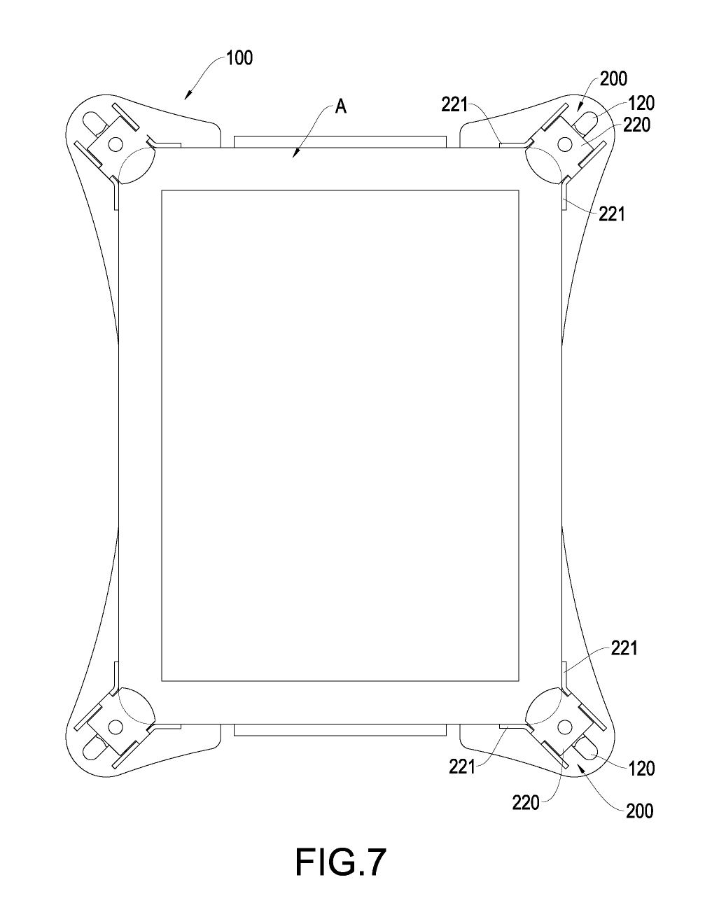

### DETAILED DESCRIPTION OF THE INVENTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

The holder for supporting a handheld electronic device of the invention includes a board 100 and at least two fastener assemblies 200. The board 100 is provided with at least two long holes 120. The at least two fastener assemblies 200 are correspondingly and separately arranged at the at least two long holes 120. Each of the fastener assemblies 200 has a post 210, a bracket 220 and a supporting pad 230. The post 210 slidably penetrates the long hole 120. The bracket 220 and supporting pad 230 are separately disposed on two opposite sides of the board 100 and at two ends of the post 210. Substantially, the bracket 220 is fixed on the board 100 and the supporting pad 230 is connecting to the post 210. Thus a handheld electronic device A can be fastened on the board 100.

The board may be made of metal for good heat dissipation or plastic for light weight. Besides, a plurality of heat dissipating holes 110 are formed in the board 110 for enhance air convection and heat dissipation.

Preferably, the board 100 is, but not limited to, a rectangle in shape. In an embodiment, the at least two long holes 120 are located at the same side of the board. In another embodiment, the at least two long holes 120 are located at two opposite angles of the board 100. However, other arrangements of the long holes 120 are also available. For example, if there are three long holes 120 in the board 100, then two of the three may be located on the same side of the board 100 and the other one is located at an angle of the board 100. Besides, a direction of each of the long holes 120 is towards a center of the board 100.

Two sides of each of the at least two long holes 120 are separately provided with two slots 130 and each of the at least two long holes 120 is parallel to adjacent two slots 130.

Each of the fastener assemblies 200 has two protrusions 240 separately penetrating the slots 130. By slidably inserting the posts 210 and protrusions 240 into the long holes 210 and slots 130 respectively, the fastener assemblies 200 can be mounted on the board 100 with linear positional adjustability resulting from a linear movement of the posts 210 in the long holes 120. Such linear positional adjustability adapts the holder to various handheld electronic devices A with different sizes. Further, the bracket 220 is provided with a fork gripper 221 for gripping a corner of the handheld electronic device A. This makes the handheld electronic device held on the board 100 more firmly.

The post 210 is provided with an outer thread 211 and the supporting pad 230 is correspondingly provided with a threaded hole 231. Thus, the supporting pad 230 can be screwed on the post 210. By releasing or fastening the supporting pad 230 to the post 210, a distance between the bracket 220 and the board 100 can be adjusted for matching various handheld electronic devices A with different thickness. Further, the support pad 230 is formed with an anti-slip shape for easy rotation. The fastener assembly 200 further includes a flexible element 250 put around the post 210 and between the bracket 220 and board 100 for preventing the supporting pad 230 from unintentionally releasing.

The at least two fastener assemblies 200 may hold the handheld electronic device A on the board 100. The positional adjustability of the fastener assemblies 200 provides adaptability for various devices with different sizes and thickness.

What is claimed is:

1. A holder for a handheld electronic device, comprising:
a board having at least two long holes; and
at least two fastener assemblies separately corresponding to the at least two long holes;
wherein each of the at least two fastener assemblies has a post penetrating one of the at least two long holes, a bracket and a supporting pad, the bracket and the supporting pad are disposed on two opposite sides of the board and at two ends of the post.

2. The holder of claim 1, wherein the board is provided with heat dissipating holes.

3. The holder of claim 1, wherein, the at least two long holes are located at the same side of the board.

4. The holder of claim 1, wherein the at least two long holes are located at two opposite angles of the board.

5. The holder of claim 1, wherein a direction of each of the at least two long holes is towards a center of the board.

6. The holder of claim 1, wherein two sides of each of the at least two long holes are separately provided with two slots, the at least two long holes are separately parallel to adjacent the two slots, and each of the fastener assemblies has two protrusions separately penetrating the slots.

7. The holder of claim 1, wherein the board is provided with a fork gripper.

8. The holder of claim 1, wherein the post is provided with an outer thread, and the supporting pad is correspondingly provided with a threaded hole for being screwed by the post.

9. The holder of claim 1, wherein the supporting pad is formed with an anti-slip shape.

10. The holder of claim 1, wherein each of the at least two fastener assemblies has a flexible element put around the post and between the board and the bracket.
